(19) United States
(12) Patent Application Publication
(10) Pub. No.: US 2026/0255655 A1
(43) Pub. Date: Aug. 27, 2026

(54) METAL-FERROELECTRIC-METAL-INSULATOR-SEMICONDUCTOR STRUCTURES

(71) Applicant: GLOBALFOUNDRIES Dresden Module One Limited Liability Company & Co. KG, Dresden (DE)

(72) Inventors: Dominik Martin Kleimaier, Dresden (DE); Stefan Dünkel, Dresden (DE); Halid Mulaosmanovic, Dresden (DE); Johannes Müller, Dresden (DE); Ralf Richter, Radebeul (DE)

(21) Appl. No.: 19/061,175

(22) Filed: Feb. 24, 2025

(51) Int. Cl. H10D 64/68; H10D 30/01; H10D 30/69

(52) U.S. Cl. CPC H10D 64/689; H10D 30/0415; H10D 30/701

(57) ABSTRACT

The present disclosure relates to semiconductor structures and, more particularly, to metal-ferroelectric-metal-insulator-semiconductor structures and methods of manufacture. The structure includes a plurality of top gate structures and a bottom gate structure comprising a metal material shared with the plurality of top gate structures.

### BACKGROUND

The present disclosure relates to semiconductor structures and, more particularly, to metal-ferroelectric-metal-insulator-semiconductor structures and methods of manufacture.

Metal-ferroelectric-metal-insulator-semiconductor (MFMIS) ferroelectric field effect transistors (FeFETs) are a type of non-volatile memory device. These devices are compatible with CMOS technology and have reliable switching characteristics. The MFMIS FeFETs have a larger memory window, fast read/write operations, low power consumption and non-destructive readout capabilities.

MFMIS FeFETs can be used in an array of different technologies including, for example, non-volatile memory applications due to their reliable switching and CMOS compatibility, in addition to neuromorphic computing in which the FeFETs are used as artificial synapses.

### SUMMARY

In an aspect of the disclosure, a structure comprises: a plurality of top gate structures; and a bottom gate structure comprising a metal material shared with the plurality of top gate structures.

In an aspect of the disclosure, a structure comprises: a plurality of top gate structures in an active region, the plurality of top gate structures comprising a first conductive layer, a ferroelectric layer and an electrode material; and a bottom gate structure comprising a second conductive layer shared with the plurality of top gate structures, the second conductive layer being underneath the ferroelectric layer.

In an aspect of the disclosure, a method comprises: forming a plurality of top gate structures; and forming a bottom gate structure comprising a metal material shared with the plurality of top gate structures.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a structure and respective fabrication processes in accordance with aspects of the present disclosure.

FIG. 2 shows a structure in accordance with additional aspects of the present disclosure.

FIG. 3A shows a top view of a structure in accordance with additional aspects of the present disclosure.

FIG. 3B shows a top view of a structure in accordance with other aspects of the present disclosure.

FIGS. 4A-4D show a non-limiting example of fabrication processes for manufacturing the structure of FIG. 1 in accordance with additional aspects of the present disclosure.

### DETAILED DESCRIPTION

The present disclosure relates to semiconductor structures and, more particularly, to metal-ferroelectric-metal-insulator-semiconductor (MFMIS) structures and methods of manufacture. More specifically, the MFMIS includes a plurality of top gate structures with a shared bottom gate structure. In embodiments, the MFMIS include a ferroelectric layer between the top gate structures and the shared bottom gate structure. Advantageously, the MFMIS exhibits less variation and parasitics/noise due to a compact construction and equalization of grain impact, in addition to providing improved device properties, e.g., reduced variation, and improved reliability which enables multi-bit sensing (e.g., 1.5 bit cell or 2.0 bit cell sensing).

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

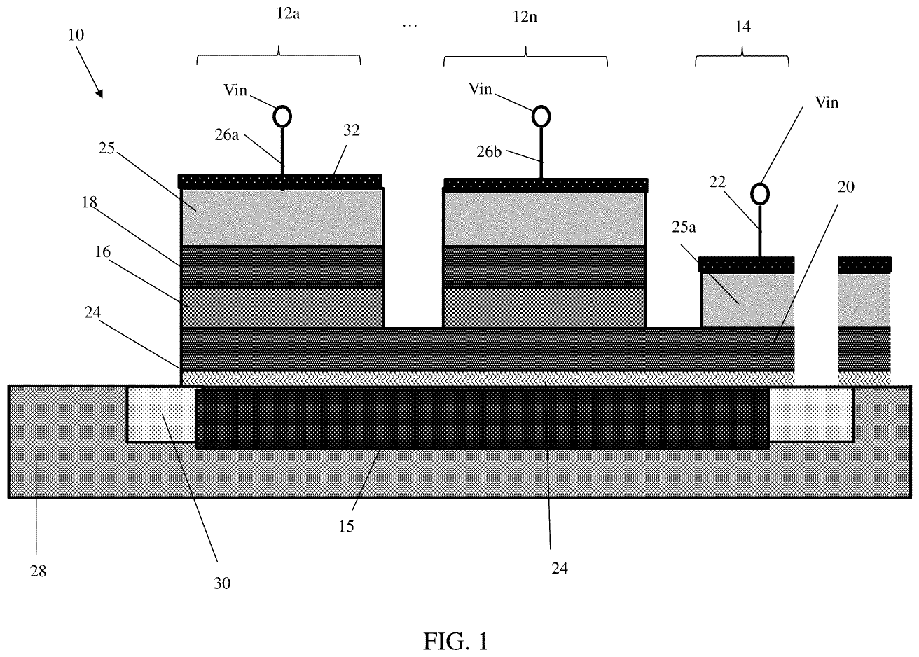

FIG. 1 shows a structure and respective fabrication processes in accordance with aspects of the present disclosure. More specifically, the structure 10 of FIG. 1 includes a plurality of top gate structures 12 a-12n (wherein “n” is an integer of 2 or more) with a shared bottom gate structure 14. As should be recognized by those of skill in the art, the plurality of top gate structures 12a-12n may include two or more gate structures, each sharing the bottom gate structure 14. The top gate structures 12a-12n may be the same dimensions or different dimensions, depending on design requirements as further described herein.

In embodiments, the top gate structures 12a-12n may be shared source/drain regions 15, requiring a single contact for the source region and a single contact for the drain region for all of the gate structures. (In the view shown in the cross sectional view of FIG. 1, only a single source region or a drain region is shown.) The shared source/drain regions 15 of the trop gate structures 12a-12n may be within a single active region. In embodiments, the shared bottom gate structure 14 and a dedicated terminal 22 may be outside of the active region.

The shared source/drain regions 15 may be provided within a semiconductor substrate 28 as is known in the art. For example, the source/drain regions 15 may be formed by an ion implantation process. Although not critical to the understanding of the present description, the ion implantation process includes introducing a dopant into the semiconductor substrate 28. In embodiments, patterned implantation masks may be used to define selected areas exposed for the implantation. The implantation mask may include a layer of a light-sensitive material, such as an organic photoresist, applied by a spin coating process, pre-baked, exposed to light projected through a photomask, baked after exposure, and developed with a chemical developer. The implantation mask has a thickness and stopping power sufficient to block masked areas against receiving a dose of the implanted ions. In embodiments, p-type dopants, e.g., Boron (B), and n-type dopants, e.g., Arsenic (As), Phosphorus (P) and Antimony (Sb), among other suitable examples, may be used to form the source/drain regions 15.

Alternatively, the shared source/drain regions 15 may be formed by an epitaxial growth process with an in-situ deposition process. In embodiments, the epitaxial growth process may form raised source/drain regions 15. Although not critical to understanding of the present disclosure, examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The epitaxial growth may be performed at a temperature of from 300° C. to 800° C. The epitaxial growth can be performed utilizing any well-known precursor gas or gas mixture. Carrier gases like hydrogen, nitrogen, helium and argon can be used. A dopant (n-type or p-type dopant) is typically added to the precursor gas or gas mixture.

The top gate structures 12a-12n may comprise a ferroelectric material 16 between a gate metal material (e.g., conductive material) 18 of the top gate structures 12a-12n and a gate metal material (e.g., conductive material) 20 of the shared bottom gate structure 14. In this way, the ferroelectric material 16 is sandwiched between the gate metal materials 18, 20, which forms a ferroelectric field effect transistor (FeFET). As should be understood by those of skill in the art, ferroelectric polarization acts as a permanent gate bias, either positive or negative depending on the polarization state. In alternative embodiments, reference numeral 16 may also be representative of dielectric material (non-ferroelectric) or anti-ferroelectric material.

In embodiments, the gate metal material 20 of the shared bottom gate structure 14 may be provided underneath the ferroelectric material 16 and the gate metal material 18 of the top gate structures 12a-12n, and which connects to a dedicated terminal (e.g., contact) 22. In embodiments, the dedicated terminal 22 may be provided in the width direction of the bottom gate structure 14; although other orientations are also contemplated herein. The top gate structures 12a-12n and the shared bottom gate structure 14 also comprise a shared gate dielectric material 24. In embodiments, the In alternative embodiments, reference numeral 24 may also be representative of ferroelectric material or anti-ferroelectric material.

The top gate structures 12a-12n each include a dedicated terminal 26a, 26b, which may provide the same voltage or different voltage to the gate structures 12a-12n (for switching of the device by polarizing the ferroelectric material 16). As should be understood by those of skill in the art, in a ferroelectric device, applying a voltage above a certain threshold (coercive voltage) causes the internal electric dipoles within the ferroelectric material to switch their orientation, effectively storing data by changing the polarization state of the material, which can be maintained even when the voltage is removed due to its inherent “memory” property.

In an example, the voltage inputs to the top gate structures 12a-12n may include: (i) high, high, (ii) low, low; (iii) high, low, and (iv) low, high. In this way, each input can be programmed individually, with intermediate Vt levels being targeted more precisely. For example, with respect to intermediate Vt levels, it is now possible to mix purely digital inputs (fully polarization switched) to behave as analog-like due to the shared bottom gate 14 without necessity to rely on partially/subloop switched polarization on individual films (grains mixed up/down would be unstable).

Further, in implementation, the application of the different voltages result in a 1.5 bit cell when the top gate structures 12a-12n are of the same size (e.g., dimension). On the other hand, the application of the different voltages results in a 2.0 bit cell when the top gate structures 12a-12n are of a different size. In this latter scenario, the different input voltages become weighted due to the different dimensions of the top gate structures 12a-12n.

The ferroelectric material 16 may be, for example, a hafnium oxide material such as silicon hafnium oxide. The ferroelectric material 16 may be other ferroelectric materials such as, for example, Lead Zirconate Titanate (PZT), Strontium Bismuth Tantalate (SBT), Barium Titanate (BaTiO₃), and/or doped Hafnium Oxide (HZO).

The gate metal materials (e.g., (e.g., conductive material) 18, 20 may be TiN or other metal or metal alloys (e.g., (e.g., conductive materials). These other materials may comprise, for example, TaN, TaAlC, TiC, TiAl, TaC, Co, Al, TiAl, HfTi, TiSi, TaSi and/or TiAlC, amongst other non-limiting examples.

The gate dielectric material 24 may be a low-k dielectric material, a high-k dielectric material or a combination thereof. For example, the low-k dielectric material may be an oxide material, whereas, the high-k dielectric material may be, e.g., HfO₂ Al₂O₃, Ta₂O₃, TiO₂, La₂O₃, SrTiO₃, LaAlO₃, ZrO₂, Y₂O₃, Gd₂O₃, and combinations including multilayers thereof.

Still referring to FIG. 1, the top gate structures 12a-12n and the shared bottom gate structure 14 include respective gate electrodes 25, 25a (reference numeral 25a represents the gate electrode of the bottom gate structure 14). The gate electrodes 25, 25a may be, for example, polysilicon material. In embodiments, the gate electrodes 25, 25a are optional such that each of the terminals 22, 26a, 26b can directly contact the gate metal materials 18, 20, respectively.

In addition, the top gate structures 12a-12n each include a dedicated terminal (e.g., contacts) 26a, 26b, similar to the dedicated terminal (e.g., contact) 22 of the shared bottom gate structure 14. In embodiments, the dedicated terminals 22, 26a, 26b may be wiring structures and interconnect structures within interlevel dielectric material as is known in the art such that no further explanation is required for a complete understanding of the present disclosure. In embodiments, the dedicated terminals 22, 26a, 26b may be connected to a voltage input, Vin.

The top gate structures 12a-12n and the shared bottom gate structure 14 may be formed on semiconductor substrate 28. The semiconductor substrate 28 may be a bulk substate comprising any suitable semiconductor material including, but not limited to, Si, SiGe, SiGeC, SiC, GaAs, InAs, InP, and other III/V or II/VI compound semiconductors. The semiconductor substrate 12 may comprise any suitable crystallographic single orientation (e.g., a (100), (110), (111), or (001) crystallographic orientation).

In alternative embodiments, the semiconductor substrate 28 may include semiconductor on insulator (SOI) technology. The SOI technology may include, from bottom to top, a handle substrate, a buried insulator layer (i.e., substrate) and a top semiconductor layer as is known in the art such that no further explanation is required for a complete understanding of the present disclosure.

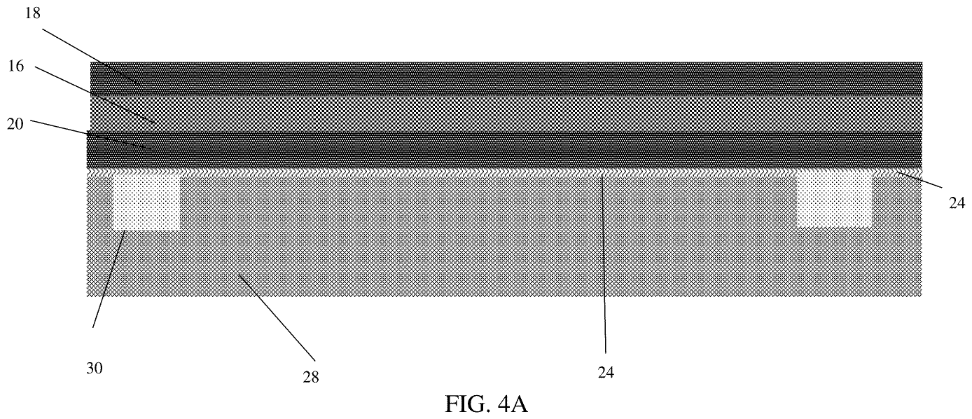

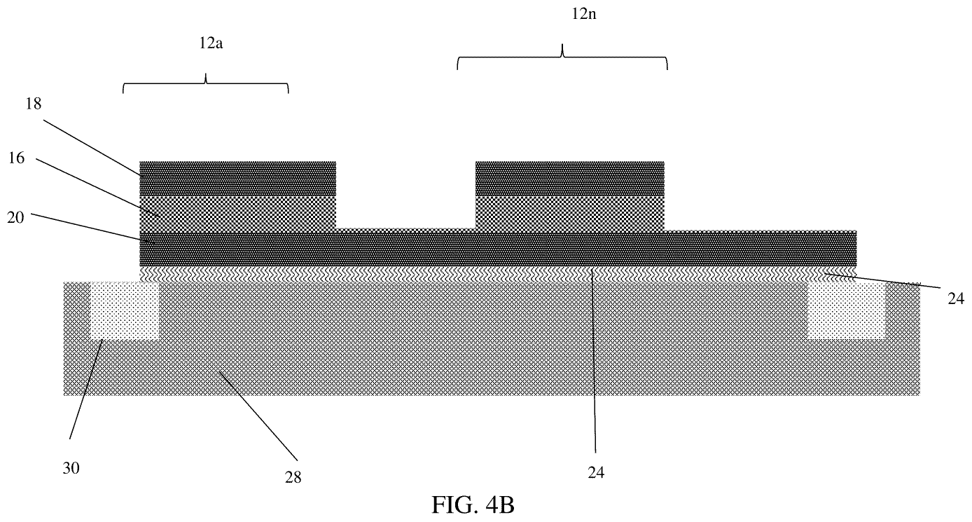

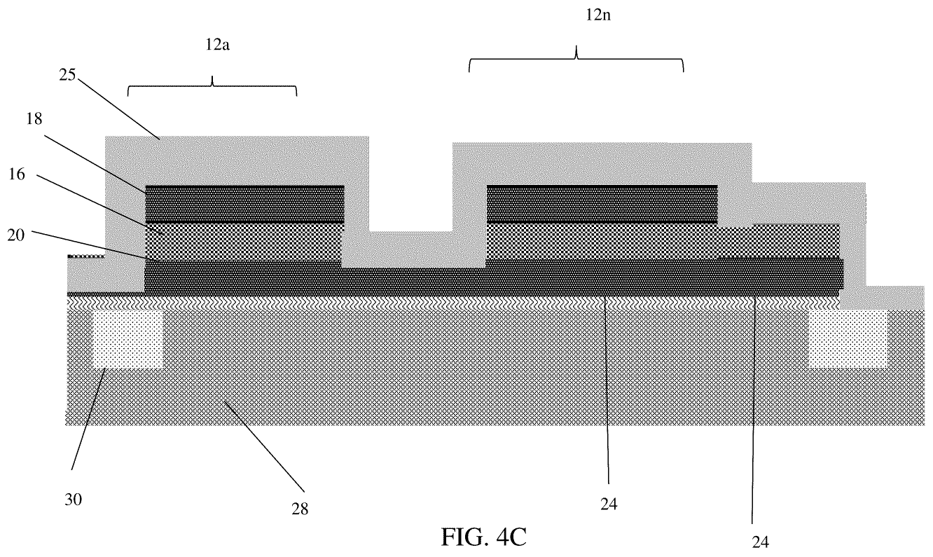

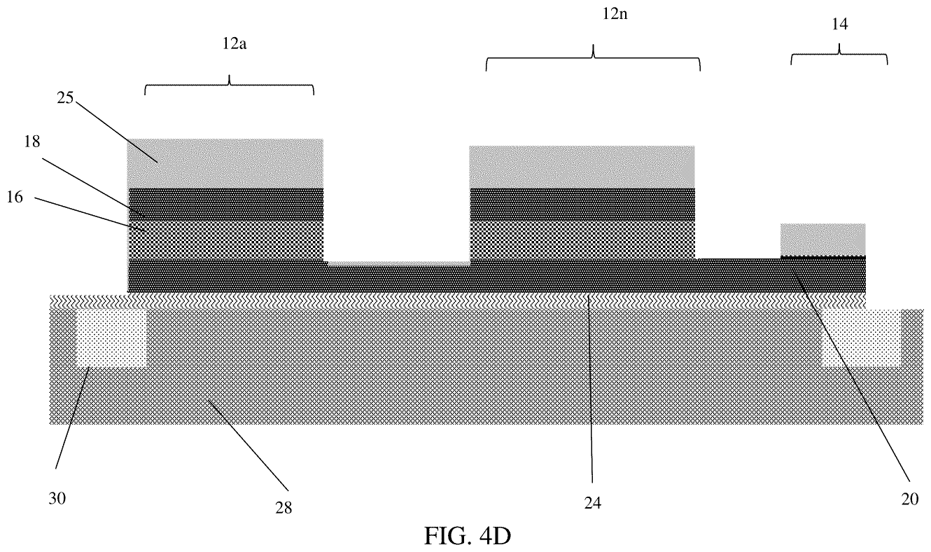

Shallow trench isolation structures 30 may be formed in the semiconductor substrate 28. The shallow trench isolation structures 30 may surround and isolate the active region, e.g., top gate structures 12a-12n and the shared bottom gate structure 14. The shallow trench isolation structures 30 can be formed by conventional lithography, etching and deposition methods known to those of skill in the art as described in FIG. 4A.

Silicide contacts 32 may be formed on an upper surface of the top gate structures 12-12n and the shared bottom gate structure 14. In embodiments, the dedicated terminals (e.g., contacts) 22, 26a, 26b may be formed on and contact the silicide contacts 32.

As should be understood by those of skill in the art, the silicide process begins with deposition of a thin transition metal layer, e.g., nickel, cobalt or titanium, over fully formed and patterned semiconductor devices (e.g., polysilicon material 25, 25a of the devices 12-12n, 14 and source/drain regions 15). After deposition of the material, the structure is heated allowing the transition metal to react with exposed silicon (or other semiconductor material as described herein) in the active regions of the semiconductor device (e.g., source/drain regions and gate contact region) forming a low-resistance transition metal silicide. Following the reaction, any remaining transition metal is removed by chemical etching, leaving silicide contacts 32 in the active regions of the device. It should be understood by those of skill in the art that silicide contacts will not be required on the devices when a top material of the gate structure is composed of a metal material.

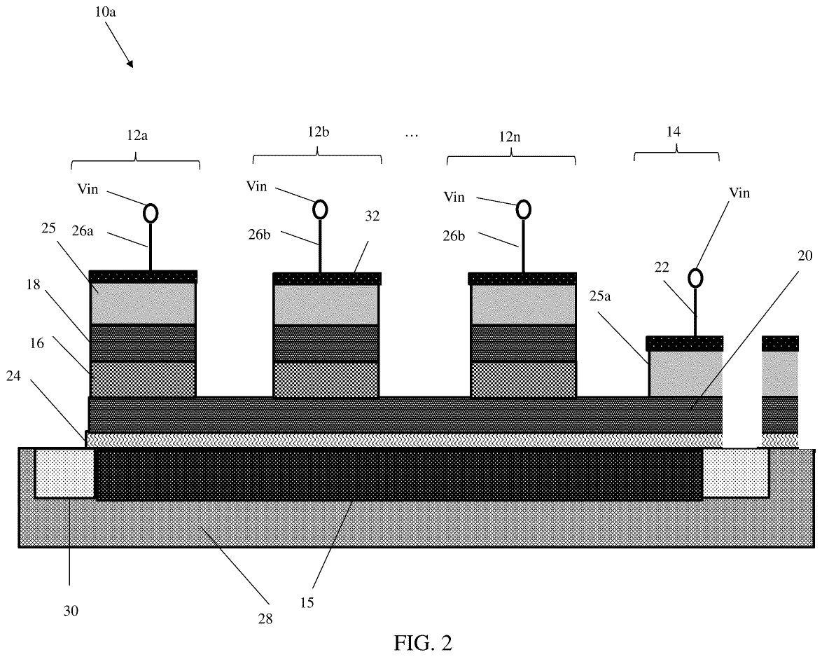

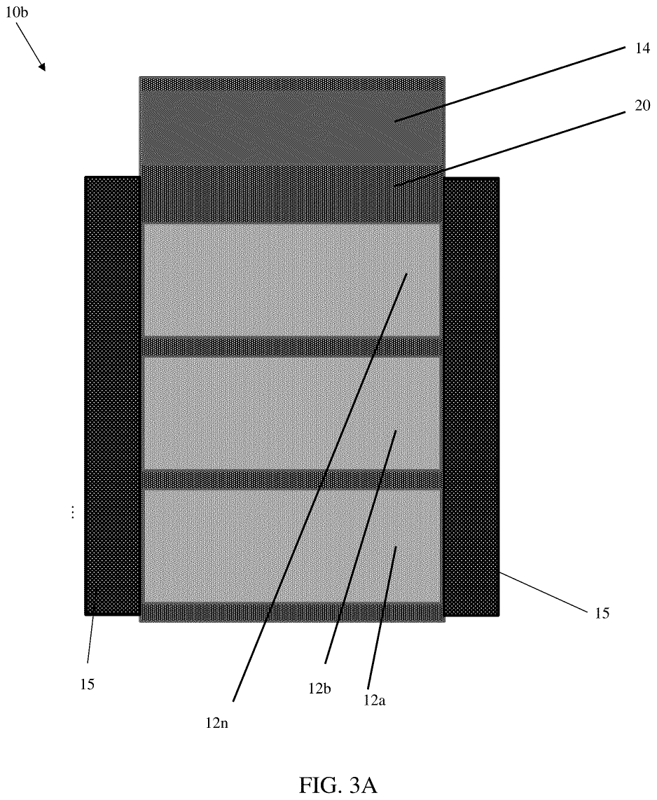

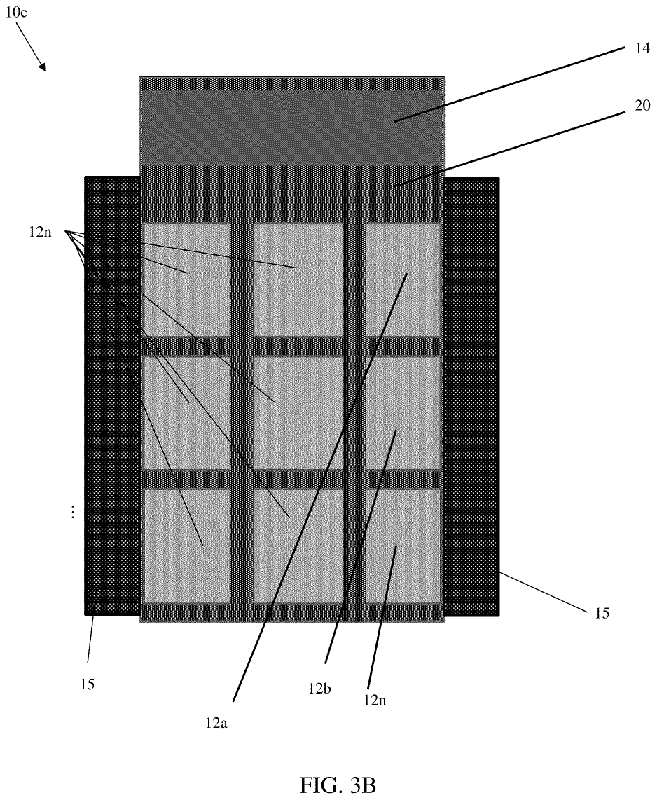

FIG. 2 shows an alternative structure in accordance with additional aspects of the present disclosure. For example, the structure 10a of FIG. 3A includes three gate structures 12a, 12b-12n and a shared bottom gate structure 14. The remaining features of FIG. 2 are similar to that of FIG. 1 such that no further explanation is required for a complete understanding of the present disclosure.

FIG. 3A shows a top view of a structure in accordance with additional aspects of the present disclosure. The structure 10b of FIG. 3A shows three top gate structures 12a, 12b-12n (e.g., array of top gate structures) and a single bottom gate structure 14. In embodiments, the top gate structures 12a, 12b-12n may be parallel or orthogonal to the single bottom gate structure 14. As further shown in this representation, the metal material 20 is shared with the top gate structures 12a, 12b-12n and the single bottom gate structure 14. In addition, the source/drain regions 15 are common to the top gate structures 12a, 12b-.

In implementation, the individual top gate structures 12a-12n and shared bottom gate structure 14 allow for program and erase operations. The program and erase operations, in addition to a read path within the semiconductor substrate 28 confined between the shallow trench isolation structures 30, can be decoupled for each input. In this way, the present structures provide decoupled reliability dependence of the ferroelectric material 16 and the gate dielectric material 24 (e.g., interface layer), while also providing improved reliability (e.g., endurance) and variability (e.g., equalization of grain impact due to lower metal layer). The improved variability results from an equalization of grain impact due to the shared lower metal material 34 between the top gate structures 12a-12n and the bottom gate structure 14.

FIG. 3B shows a top view of a structure in accordance with other aspects of the present disclosure. The structure 10c of FIG. 3B shows another array pattern of top gate structures 12a, 12b-12n (e.g., array of top gate structures) and a single bottom gate structure 14. In this embodiment, the array of top gate structures 12a, 12b-12n comprise a grid of 3×3 gate structures. It should be recognized that other patterns may also be implemented within aspects of the present disclosure, e.g., 2×2, 4×4 m, etc. In this embodiment, the top gate structures 12a, 12b-12n may be parallel or orthogonal to the single bottom gate structure 14. As further shown in this representation, the metal material 20 is shared with the top gate structures 12a, 12b-12n and the single bottom gate structure 14. In addition, the source/drain regions 15 are common to the top gate structures 12a, 12b-12n.

In embodiments, the structures described herein provide improved (e.g., less) variation and parasitics/noise due to the compact construction and equalization of grain impact. In addition, better differentiation of multiple bits is provided due to the use of multiple top gate structures with a ferroelectric material. The structures also exhibit a reduced depolarization field with MFMIS area control and area-ratio tuning possible for memory window tuning. Also, the memory-window is enlarged compared to a FeFET due to a small area-ratio of the top gate structures 12a-12n and the shared bottom gate structure 14. The structures also have a smaller footprint as one less terminal is required for each input.

The structures also enable neuromorphic networks and multibit-cell FeFET operations, with any number of multiple input synapses. For example, the structures described herein can be implemented in deep Neural Networks (DNNs) and Spiking Neural Networks (SNNs). As such, the structures described herein may be building blocks for neural networks/neuromorphic computing, with the storage of synaptic weight being used for training, as an example.

FIGS. 4A-4D show fabrication processes to manufacture the structure of FIG. 1 in accordance with aspects of the present disclosure. The processing steps of FIGS. 4A-4D may also be used to manufacture the structure 10a of FIG. 2, as well as other structures comprising multiple top gate structures with a shared bottom gate structure. It should also be recognized by those of skill in the art that the processing steps shown in FIGS. 4A-4D are non-limiting examples and that other patterning and deposition steps, in a similar sequence or different sequence, may be used to manufacture the structures of FIGS. 1 and 2.

In FIG. 4A, shallow trench isolation structures 30 may be formed in the semiconductor substrate 28. The shallow trench isolation structures 30 can be formed by conventional lithography, etching and deposition methods known to those of skill in the art. For example, a resist formed over the semiconductor substrate 28 is exposed to energy (light) and developed utilizing a conventional resist developer to form a pattern (opening). An etching process with a selective chemistry, e.g., reactive ion etching (RIE), will be used to transfer the pattern from the patterned photoresist layer to the semiconductor substrate 28 to form one or more trenches in the semiconductor substrate 28 through the openings of the resist. Following the resist removal by a conventional oxygen ashing process or other known stripants, the insulator material (e.g., silicon dioxide) can be deposited by any conventional deposition processes, e.g., chemical vapor deposition (CVD) processes. Any residual material on the surface of the semiconductor substrate 28 can be removed by conventional chemical mechanical polishing (CMP) processes.

Still referring to FIG. 4A, a gate dielectric material 24, a gate metal material 20 of the shared bottom gate structure 14, a ferroelectric material 16, and a gate metal material 18 of the top gate structures 12a-12n may be formed by separate blanket deposition processes. For example, the deposition processes may be chemical vapor deposition (CVD), physical vapor deposition (PVD) including sputtering, atomic layer deposition (ALD) or other suitable method.

In FIG. 4B, the gate dielectric material 24, gate metal material 20 of the shared bottom gate structure 14, ferroelectric material 16, and gate metal material 18 of the top gate structures 12a-12n may be patterned using conventional lithography and etching processes. In embodiments, the etching process may comprise several patterning steps. For example, a first patterning step may etch the gate dielectric material 24, gate metal material 20, ferroelectric material 16, and gate metal material 18 to within the confines of the shallow trench isolation structures 30, followed by a second patterning step of etch the ferroelectric material 16 and gate metal material 18 to form the base of the top gate structures 12a-12n. In this approach, the gate dielectric material 24 and gate metal material 20 of the shared bottom gate structure 14 will remain intact and extend to under the top gate structures 12a-12n. The ferroelectric material 16 will remain sandwiched between the gate metal materials 18, 20.

In FIG. 4C, a gate electrode 25, e.g., polysilicon material, may be blanket deposited over the entire structure. In embodiments, the gate electrode 25 may be deposited or grown using any known method as should be understood by those of skill in the art.

In FIG. 4D, the gate electrode 25, e.g., polysilicon material, may be etched to remove the material between the top gate structures 12a-12n and between the top gate structure 12n and the bottom gate structure 12. In this way, the gate electrode 25, e.g., polysilicon material, will remain on the ferroelectric material 16 of the top gate structures 12a-12n and over the gate metal material 20 of the bottom gate structure 14, thereby forming the top gate structures 12a-12n and the bottom gate structure 14. The processes may continue to form the silicide contacts and dedicated terminals as further described with respect to FIG. 1

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a plurality of top gate structures; and
a bottom gate structure comprising a metal material shared with the plurality of top gate structures.

2. The structure of claim 1, wherein the plurality of top gate structures comprise a top metal material provided over the metal material of the bottom gate structure.

3. The structure of claim 2, further comprising a ferroelectric material sandwiched between the top metal material of the plurality of top gate structures and the metal material of the bottom gate structure.

4. The structure of claim 3, wherein the bottom gate structure comprises a dedicated contact terminal and the plurality of top gate structures each comprise other dedicated contact terminals.

5. The structure of claim 4, wherein the dedicated contact terminals connect to an input voltage.

6. The structure of claim 3, wherein the plurality of top gate structures comprise at least two top gate structures which share the metal material of the bottom gate structure.

7. The structure of claim 6, wherein the plurality of top gate structures share source/drain regions.

8. The structure of claim 3, wherein the bottom gate structure is provided in a width direction with respect to the plurality of top gate structures.

9. The structure of claim 3, wherein the bottom gate structure is outside an active region comprising the plurality of top gate structures.

10. The structure of claim 9, further comprising shallow trench isolation structures which isolate the active region.

11. The structure of claim 3, wherein the bottom gate structure and the plurality of top gate structures share a gate dielectric material with the bottom gate structure.

12. The structure of claim 1, wherein the plurality of top gate structures comprise metal-ferroelectric-metal-insulator-semiconductor (MFMIS) structures and the bottom gate structure comprises the metal material and an underlying dielectric material.

13. The structure of claim 1, wherein a gate electrode of the bottom gate structure and the plurality of top gate structures are provided above the top metal material of the plurality of top gate structures and the metal material of the bottom gate structure.

14. A structure comprising:
a plurality of top gate structures in an active region, the plurality of top gate structures comprising a first conductive layer, a ferroelectric layer and an electrode material; and
a bottom gate structure comprising a second conductive layer shared with the plurality of top gate structures, the second conductive layer being underneath the ferroelectric layer.

15. The structure of claim 14, wherein the plurality of top gate structures and the bottom gate structure share a common gate dielectric material.

16. The structure of claim 14, wherein the plurality of top gate structures comprise shared source/drain regions in the active region.

17. The structure of claim 14, further comprising shallow trench isolation structures isolating the active region.

18. The structure of claim 14, wherein the bottom gate structure comprises a dedicated contact terminal and the plurality of top gate structures comprise other dedicated contact terminals.

19. The structure of claim 14, wherein the plurality of top gate structures comprise metal-ferroelectric-metal-insulator-semiconductor (MFMIS) structures and the bottom gate structure comprises the second conductive layer and an underlying dielectric material.

20. A method comprising:
forming a plurality of top gate structures on a semiconductor substrate; and
forming a bottom gate structure comprising a metal material shared with the plurality of top gate structures.
